(19) United States
(12) Patent Application Publication
(10) Pub. No.: US 2025/0224462 A1
(43) Pub. Date: Jul. 10, 2025

(54) DEVICE FOR MEASURING ASYMMETRICAL MAGNETOTRANSPORT PROPERTY COUPLED WITH ELECTROMOTIVE FORCE

(71) Applicant: Korea University Research and Business Foundation, Seoul (KR)

(72) Inventors: Young Keun KIM, Seoul (KR); Yoo Sang JEON, Seoul (KR); Eunjin JEONG, Seoul (KR)

(73) Assignee: Korea University Research and Business Foundation, Seoul (KR)

(21) Appl. No.: 19/013,455

(22) Filed: Jan. 8, 2025

(30) Foreign Application Priority Data
Jan. 8, 2024 (KR) 10-2024-0002926

(51) Int. Cl. G01R 33/028

(52) U.S. Cl. CPC G01R 33/0286

(57) ABSTRACT

The present invention relates to utilizing a prepared chiral ferromagnetic nanomaterial for a spintronic nanomaterial, such as an actual magnetic memory, and a device for measuring the asymmetrical magnetotransport property coupled with an electromotive force may include a rotating device that generates a rotational motion in an electrode; a stack stacked on the electrode; a chiral nanostructure in which a chiral ferromagnetic nanocoil is deposited on the stack, and, in response to the rotating device rotating, chirality-induced spin selectivity or the asymmetrical magnetotransport property may be measured through the chiral nanostructure.

### CROSS-REFERENCE TO RELATED APPLICATION(S)

This application claims priority from and the benefit of Korean Patent Application No. 10-2024-0002926 filed on Jan. 8, 2024, which is hereby incorporated by reference in its entirety.

### BACKGROUND

### 1. Field

The present invention relates to utilizing a prepared chiral ferromagnetic nanomaterial for a spintronic nanomaterial, such as an actual magnetic memory, and more particularly, to measurement technology for improving the degree of spin polarization by simultaneously expressing chiral-based property, such as asymmetric electromotive force generation and chirality-induced spin selectivity (CISS) according to the direction by Faraday's law of electromagnetic induction occurring at nanoscale, and, based thereon, acquiring asymmetric electromotive force generation according to the direction by assigning chirality and resulting chirality-induced spin selectivity, and the magnetoresistance effect.

### 2. Related Art

Chirality with a mirror-image symmetry structure is expressed in various natural fields, and this property is mainly utilized in physics, chemistry, life science, and optics.

In particular, chiral molecules are utilized in sensors, biochemistry, biomedical, and optical equipment.

A chiral molecule refers to a molecule that has false symmetry since the molecule is not mirror image symmetrical. Such chiral molecules have specific optical properties and accordingly, may have a specific direction of rotation when interacting with (polarized) light rays or electrons. In particular, chiral molecules with each handedness may have the property of selectively passing specific (up or down) spins of electrons.

Chiral molecules may produce the chirality-induced spin selectivity of selectively allowing electrons in a specific spin direction to pass, in response to an external voltage being applied. This is a phenomenon in which current may be controlled according to the spin direction of electrons and may be applied in the field of nano-electromagnetic fields and nano-electronic devices.

Such chiral molecules and chirality-induced spin selectivity may be utilized in sensor technology to detect specific compounds and biological molecules. Also, in the biomedical field, chiral molecules may be used to detect and manipulate specific molecules or cells within the living body. In the field of optics, the spin of light may be controlled to provide new functions in optical communication or optoelectronic devices.

Technology using chirality and spin-selective properties presents innovative application probability in various fields including future nano-electronic devices, optoelectronic devices, and the medical field.

In particular, chiral molecules may create the phenomenon, such as chirality-induced spin selectivity, of selectively allowing electrons in a specific spin direction to pass when electrons flow due to an external voltage.

Patent documents include (Patent document 1) Japanese Patent Publication No. 2023-139660 “Measurement method and measurement device,” (Patent document 2) Korean Patent Publication No. 10-2023-0013259 “Use of magnetic nanoparticles for detection and quantitation of analyte(s),” (Patent document 3) Korean Patent Registration No. 10-1148016 “Electromotive force measurement system using nanowire and electromotive force measurement method using the same,” and (Patent document 4) European Patent Registration No. 2872911 “Micromagnetometry detection system and method for detecting magnetic signatures of magnetic materials.”

### SUMMARY

The present invention aims to provide a method of further maximizing the chiral-based magnetic properties presented in the art while applying a very efficiently changing magnetic field to an inorganic material-based nanomaterial.

The present invention aims to acquire an asymmetric electromotive force according to the chirality (chiral direction).

The present invention aims to acquire a relatively large magnetoresistance effect in consideration of a characteristic of a ferromagnetic material.

The present invention aims to utilize a prepared chiral ferromagnetic nanomaterial for a spintronic nanomaterial such as an actual magnetic memory.

The present invention aims to improve the degree of spin polarization by simultaneously expressing the chiral-based property, such as asymmetric electromotive force generation and chirality-induced spin selectivity (CISS) according to the direction by Faraday's law of electromagnetic induction occurring at nanoscale.

According to an aspect, there is provided a device for measuring the asymmetrical magnetotransport property coupled with an electromotive force, the device including a rotating device that generates a rotational motion in an electrode; a stack stacked on the electrode; a chiral nanostructure in which a chiral ferromagnetic nanocoil is deposited on the stack, wherein, in response to the rotating device rotating, chirality-induced spin selectivity or the asymmetrical magnetotransport property is measured through the chiral nanostructure.

The stack may have differences in characteristics by magnetic field between in-plane and out-of-plane and may have the characteristic of having an easy axis of magnetization in the in-plane direction or the out-of-plane direction when an external magnetic field is absent.

The stack may include a form in which cobalt and platinum are stacked.

The chiral ferromagnetic nanocoil may be synthesized electrochemically using an anodic aluminum oxide nanopore template.

The rotating device may rotate the chiral nanostructure in a situation in which the magnetic field of constant intensity is applied and may generate the electromotive force based on the flux that changes with respect to the rotating magnetic field.

Based on the flux that changes with respect to the rotating magnetic field, the electromotive force may be generated based on the surface of the nanostructures, electric field, unit length, unit time, magnetic density, unit area, electromotive force, number of turns (windings) of the nanocoil, and flux change, and may be expressed as:

$$ϵ ( t ) \approx {nAB}_{0} ( 2 π f ) sin ( 2 π f t ) \qquad [ Equation 1 ]$$

In Equation 1, n denotes the concentration or total amount of chiral ferromagnetic nanocoil, A denotes the area inside the chiral ferromagnetic nanocoil (where the magnetic flux goes through), B₀ denotes the intensity of an external magnetic field, f denotes a rotation period, and t denotes an elapsed time.

In the chiral nanostructure, the chiral ferromagnetic nanocoils may be aligned on the stack by applying a straight magnetic field.

According to an aspect, there is provided a manufacturing method of a device for measuring the asymmetrical magnetotransport property coupled with an electromotive force, the method includes forming an electrode on a rotating device that generates a rotational motion; preparing a stack by sequentially stacking one or more elements on the electrode, the stack having differences in characteristics by magnetic field between in-plane and out-of-plane and having the characteristic of having an easy axis of magnetization in the in-plane direction or the out-of-plane direction when an external magnetic field is absent; forming a chiral nanostructure by depositing a chiral ferromagnetic nanocoil on the prepared stack, wherein, in response to the rotating device rotating, chirality-induced spin selectivity or the asymmetrical magnetotransport property is measured through the chiral nanostructure.

The forming of the chiral nanostructure by depositing the chiral ferromagnetic nanocoil on the prepared stack may include synthesizing the chiral ferromagnetic nanocoil electrochemically using an anodic aluminum oxide nanopore template; and depositing the chiral ferromagnetic nanocoil on the prepared stack by applying a straight magnetic field and by controlling the synthesized chiral ferromagnetic nanocoils to be aligned on the stack.

According to example embodiments, it is possible to provide a method of further maximizing the chiral-based magnetic properties presented in the art while applying a very efficiently changing magnetic field to an inorganic material-based nanomaterial.

According to example embodiments, it is possible to acquire an asymmetric electromotive force according to the chirality (chiral direction).

According to example embodiments, it is possible to acquire a relatively large magnetoresistance effect in consideration of a characteristic of a ferromagnetic material.

According to example embodiments, it is possible to utilize a prepared chiral ferromagnetic nanomaterial for a spintronic nanomaterial such as an actual magnetic memory.

According to example embodiments, it is possible to improve the degree of spin polarization by simultaneously expressing chiral-based property, such as asymmetric electromotive force generation and chirality-induced spin selectivity (CISS) according to the direction by Faraday's law of electromagnetic induction occurring at nanoscale.

Further areas of applicability will become apparent from the description provided herein. The description and specific examples in this summary are intended for purposes of illustration only and are not intended to limit the scope of the present disclosure.

### BRIEF DESCRIPTION OF THE FIGURES

Embodiments will be described in more detail with regard to the figures, wherein like reference numerals refer to like parts throughout the various figures unless otherwise specified, and wherein:

FIG. 1 illustrates a device for measuring the asymmetrical magnetotransport property coupled with an electromotive force according to an example embodiment;

FIGS. 2A to 2E show schematic views of the present invention;

FIG. 3 is a graph showing the results of measuring the magnetic property of a stack using a vibrating sample magnetometer (VSM);

FIGS. 4A to 4E are graphs showing results of verifying the chirality-induced spin selectivity property of chiral ferromagnetic nanocoils that has right or left handedness; and

FIGS. 5A to 5C are graphs showing the magnetotransport property according to the direction of an external magnetic field.

### DETAILED DESCRIPTION

The specific structural or functional descriptions of example embodiments according to the concept of the present invention described herein are merely intended for the purpose of describing the example embodiments according to the concept of the present invention and the example embodiments according to the concept of the present invention may be implemented in various forms and are not construed as limited to the example embodiments described herein.

Various modifications and various forms may be made to the example embodiments according to the concept of the present invention and thus, the example embodiments are illustrated in the drawings and described in detail through the present specification. However, it should be understood that the example embodiments according to the concept of the present invention are not construed as limited to specific implementations and should be understood to include all changes, equivalents, and replacements within the idea and the technical scope of the present invention.

Although terms of “first,” “second,” and the like are used to explain various components, the components are not limited to such terms. These terms are used only to distinguish one component from another component. For example, a first component may be referred to as a second component, or similarly, the second component may be referred to as the first component without departing from the scope according to the concept of the present invention.

When it is mentioned that one component is “connected” or “accessed” to another component, it may be understood that the one component is directly connected or accessed to another component or that still other component is interposed between the two components. In addition, when it is described that one component is “directly connected” or “directly accessed” to another component, it should be understood that still other component is absent therebetween. Likewise, expressions describing relationships between components, for example, “between” and “immediately between” and “immediately adjacent to” may also be construed as described in the foregoing.

The terminology used herein is for the purpose of describing particular example embodiments only and is not to be limiting of the present invention. As used herein, the singular forms “a,” “an,” and “the” are intended to include the plural forms as well, unless the context clearly indicates otherwise. It will be further understood that the terms “comprises/includes” or “has,” when used in this specification, specify the presence of stated features, integers, stages, operations, components, parts, or combinations thereof, but do not preclude the presence or addition of one or more other features, integers, stages, operations, components, parts, or combinations thereof.

Unless otherwise defined herein, all terms used herein including technical or scientific terms have the same meanings as those generally understood by one of ordinary skill in the art. Terms defined in dictionaries generally used should be construed to have meanings matching contextual meanings in the related art and are not to be construed as an ideal or excessively formal meaning unless otherwise defined herein.

Hereinafter, example embodiments will be described in detail with reference to the accompanying drawings. However, the scope of the claims is not limited to or restricted by the example embodiments. Like reference numerals presented in the respective drawings refer to like components throughout.

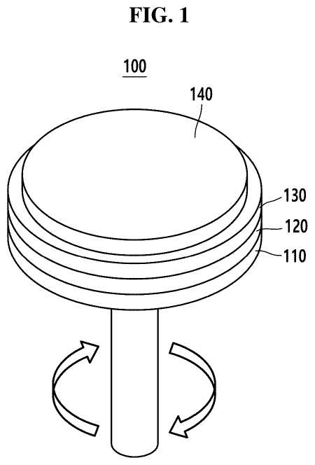

FIG. 1 illustrates a device 100 for measuring the asymmetrical magnetotransport property coupled with an electromotive force according to an example embodiment.

The present invention may overcome the limitations found in the conventional method of measuring the magnetotransport effect using chiral organic molecules. The conventional method statistically processes measurement results from various areas using tools such as conductive atomic microscopy, which makes it difficult to acquire comprehensive results.

Therefore, the device 100 for measuring the asymmetrical magnetotransport property coupled with the electromotive force according to an example embodiment uses an inorganic material-based chiral ferromagnetic nanomaterial and thus, may precisely measure results that respond to an external magnetic field without a need for an organic molecule measurement method.

In detail, the device 100 for measuring the asymmetrical magnetotransport property coupled with the electromotive force according to an example embodiment may include a rotating device that generates a rotational motion in an electrode 110, a stack (120, 130) stacked on the electrode 110, and a chiral nanostructure 140 in which a chiral ferromagnetic nanocoil is deposited on the stack (120, 130).

According to an example embodiment, the chiral ferromagnetic nanocoil deposited on the stack may be made of a conductive ferromagnetic material including all of Co, Fe, Ni, and other alloys containing the same.

Also, a manufacturing method of the device 100 for measuring the asymmetrical magnetotransport property coupled with the electromotive force may form the electrode 110 on the rotating device that generates a rotational motion and may prepare the stack by sequentially stacking one or more elements 120 and 130 on the formed electrode 110. This stack may be prepared using an element that has differences in characteristics by magnetic field between in-plane and out-of-plane and has the characteristic of having an easy axis of magnetization in the in-plane direction or the out-of-plane direction when an external magnetic field is absent. The chiral nanostructure 140 may be formed by depositing the chiral ferromagnetic nanocoil on the prepared stack.

According to an example embodiment, to form the chiral nanostructure 140 by depositing the chiral ferromagnetic nanocoil on the prepared stack, the chiral ferromagnetic nanocoil may be synthesized electrochemically using an anodic aluminum oxide nanopore template and the synthesized chiral ferromagnetic nanocoils may be controlled to be aligned on the stack by applying a straight magnetic field. Therefore, the manufacturing method of the device 100 may deposit the chiral ferromagnetic nanocoil on the stack.

The rotating device may rotate the chiral nanostructure 140 in a situation in which the magnetic field of constant intensity is applied and may generate the electromotive force based on the flux that changes with respect to the rotating magnetic field.

Also, as the electrode 110 rotates by way of the rotating device, chirality-induced spin selectivity or the asymmetrical magnetotransport property may be measured through the chiral nanostructure 140.

The stack (120, 130) used herein may variously use any element that has differences in characteristics by magnetic field between in-plane and out-of-plane and has the characteristic of having an easy axis of magnetization in the in-plane direction or the out-of-plane direction when the external magnetic field is absent.

For example, the stack may include a form in which cobalt and platinum are stacked.

Meanwhile, the chiral ferromagnetic nanocoil may be synthesized electrochemically using the anodic aluminum oxide nanopore template and may be deposited on the stack (120, 130).

This chiral nanostructure 140 may acquire the asymmetric electromotive force particularly according to the chiral direction and may acquire the relatively large magnetoresistance effect since the chiral nanostructure 140 is configured using a ferromagnetic material.

The present invention may be utilized to maximize the chiral-based magnetic properties presented in the art by applying a very efficiently changing magnetic field to the inorganic material-based chiral nanostructure 140.

Currently, many methods of manufacturing a new device based on organic molecules and then performing measurement using conductive atomic force microscopy are used. However, the device 100 for measuring the asymmetrical magnetotransport property coupled with the electromotive force according to the present invention may acquire the asymmetric electromotive force according to the chirality (chiral direction) through the chiral-based magnetotransport effect of the chiral nanostructure 140.

To directly measure this, new magnetic field change technology is required. Fine electromotive force generation in the chiral nanostructure 140 is difficult to measure due to its small magnitude and requires a very large change in the intensity of the external magnetic field.

The device 100 for measuring the asymmetrical magnetotransport property coupled with the electromotive force according to an example embodiment may measure not only the fine electromotive force by chiral ferromagnetism of nanomaterial but also chirality-induced spin selectivity and the coupling effect between two phenomena.

The device 100 for measuring the asymmetrical magnetotransport property coupled with the electromotive force according to an example embodiment may contribute to the development of spintronic devices by verifying the chirality-based asymmetrical magnetotransport effect and may have a significant impact on future application in the wider range of field.

For reference, the chiral ferromagnetic nanocoil is synthesized electrochemically using the anodic aluminum oxide nanopore template. Each pore is in a cylindrical shape with a diameter of 200 nm and a height of 60 μm, and is aligned in a uniform hexagonal matrix.

To synthesize the material with an electrochemical method, silver (Ag) with a thickness of 300 nm, which acts as a cathode, is coated on one side of the corresponding nanopore template using an e-beam evaporator, and a platinum (Pt) plate is used as an anode material.

Cobalt (II) sulfate heptahydrate (Co(SO₄)₂·7H₂O, 80 mM) and iron (II) sulfate heptahydrate (Fe(SO₄)₂·7H₂O, 80 mM) are used as metal precursors, vanadium (IV) oxide sulfate hydrate (VOSO₄·xH₂O, 60 mM) and L-ascorbic acid (C₆H₈O₆, 80 mM) are used as additives, and, as chiral molecules, cinchonine hemisulfate salt (C₁₉H₂₂N₂O·½H₂SO₄, 0.01 mM) (hereinafter, cinchonine) and cinchonidine (C₁₉H₂₂N₂O, 0.01 mM) (hereinafter, cinchonidine) are used as chiral derives in the right direction and the left direction, respectively.

After mixing the above materials, a small amount of nitric acid (HNO₃) is added to adjust pH of the solution to 1.0 to 3.0, and then filled into the nanopore template for electrodeposition.

After the material is synthesized, the cathode is removed with an iodine (I)-based silver etchant, the nanopore template is dissolved with sodium hydroxide (NaOH), and the chiral ferromagnetic nanocoil, which is washed several times, is dispersed in ethanol (C₂H₆O).

By Faraday's law of electromagnetic induction, a solenoid may generate the electromotive force (emf) according to the changing external magnetic flux.

This phenomenon is expected to be similarly induced in the chiral ferromagnetic nanocoil.

However, since a flux change amount is proportional to a cross-sectional area of the coil, the magnitude is expected to be very small in the chiral ferromagnetic nanocoil.

Therefore, it is very difficult to measure this change. To solve this issue, the present invention may generate the electromotive force based on the flux that changes with respect to the rotating magnetic field by rotating the nanomaterial in a situation in which the magnetic field of constant intensity is applied. Here, since the generated electromotive force may be derived by the following formula, it can be seen that the fine electromotive force is generated in the actual chiral ferromagnetic nanocoil by controlling the presented variables.

The micro electromotive force in the chiral ferromagnetic nanocoil may be expressed as

$${∮}_{\partial \sum } E \cdot dl = - \frac{d}{dt} {\int }_{\sum } B \cdot dA$$

and may be simplified as

$$ϵ = - N \frac{d ϕ}{dt} .$$

Here, Σ, E, dl, dt, B, dA, ε, N, and dφ represent the surface of the nanostructures, electric field, unit length, unit time, magnetic density, unit area, electromotive force, number of turns (windings) of the nanocoil, and flux change, respectively.

Using this electromotive force formula, the chiral ferromagnetic nanocoils are aligned on a rotatable electrode.

A method of aligning an element includes a method of depositing a material while applying an appropriate external straight magnetic field. A method of placing an element having a special stack on an electrode may also be employed.

In the case of rotating the electrode, from the perspective of the chiral ferromagnetic nanocoil, the intensity of the magnetic field appears to change in the form of a cosine function over time.

Substituting the magnetic field flux in the form of the cosine function into the above formula, the change in the electromotive e force may be expressed as

$$ϵ ( t ) \approx - n \frac{{AB}_{0} d ( cos 2 π f t )}{dt} ,$$

as a function over time.

Here, n denotes the concentration or total amount of chiral ferromagnetic nanocoil, A denotes the area inside the chiral ferromagnetic nanocoil (where the magnetic flux goes through), B₀ denotes the intensity of the external magnetic field, f denotes a rotation period, and t denotes an elapsed time.

By expanding the above equation, the final fine electromotive force intensity over time may be acquired as follows.

That is, based on the flux that changes with respect to the rotating magnetic field, the electromotive force may be generated based on the surface of the nanostructures, electric field, unit length, unit time, magnetic density, unit area, electromotive force, number of turns (windings) of the nanocoil, and flux change, and may be expressed as Equation 1.

$$ϵ ( t ) \approx {nAB}_{0} ( 2 π f ) sin ( 2 π f t ) \qquad [ Equation 1 ]$$

In Equation 1, n denotes the concentration or total amount of chiral ferromagnetic nanocoil, A denotes the area inside the chiral ferromagnetic nanocoil where the magnetic flux goes through), B₀ denotes the intensity of the external magnetic field, f denotes the rotation period, and t denotes an elapsed time.

An area of the chiral ferromagnetic nanocoil is constant. Therefore, it can be verified that the change in the electromotive force is in the form of a linear function by changing the concentration of the chiral ferromagnetic nanocoil, the intensity of the external magnetic field, and the rotation period of the electrode as variables that may be verified in the example embodiment.

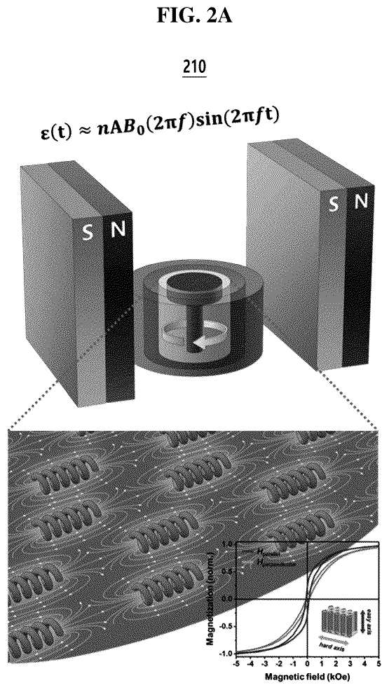

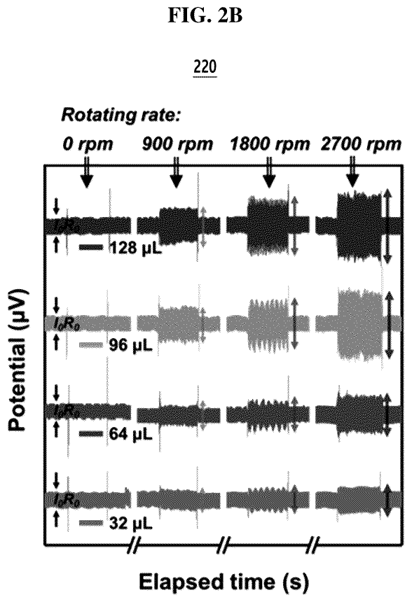

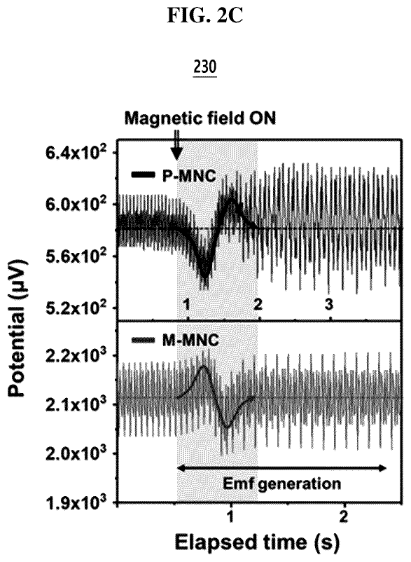

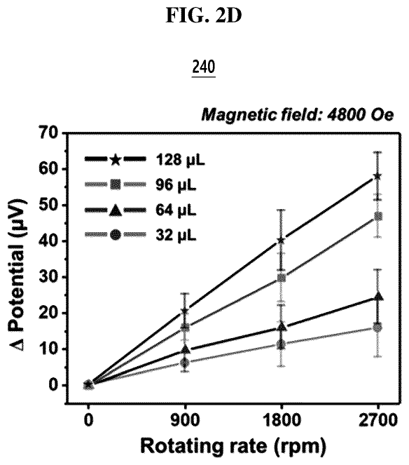

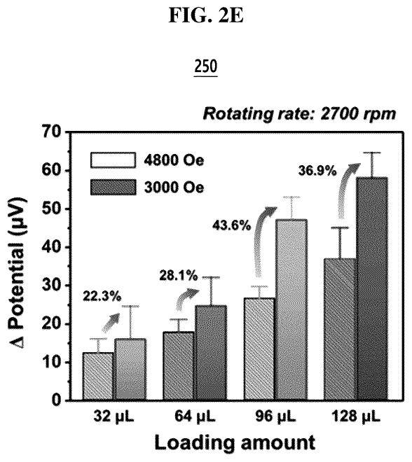

FIGS. 2A to 2E show schematic views of the present invention.

FIG. 2A shows a schematic view of a system of the present invention.

In particular, FIG. 2A illustrates a magnetic field application device capable of generating magnetetic fields of various magnitudes and a rotating device that generates a rotational motion in an electrode by the magnetic fields of various magnitudes generated by the magnetic field application device.

FIG. 2A shows the electromotive force generated in chiral ferromagnetic nanocoils aligned on the electrode (stack), as the overall system. Here, since the chiral ferromagnetic nanocoil has the coil direction that facilitates magnetization, it shows that the chiral ferromagnetic nanocoils are aligned.

FIG. 2B directly shows an amount of change in the electromotive force that changes according to the concentration and the rotation period.

Measurement was performed at the concentration of each of 32 μL, 64 μL, 96 μL, and 128 μL, and the rotation period was a rotating rate and Potential (μV) during the elapsed time was measured in order of 0 rpm, 900 rpm, 1800 rpm, and 2700 rpm.

In FIG. 2C, it can be seen that electromotive force generation starts with opposite signals at the very beginning when the electromotive force is generated according to the chirality of the chiral ferromagnetic nanocoil. Also, it was verified that it has a sine function as previously predicted.

FIG. 2D shows the change in Potential (μV), that is, the degree of electromotive force generation according to the concentration and the rotation period of the electrode, based on data of FIG. 2B. As in the formula, linear functional characteristics are shown for each concentration and rotating rate. For reference, FIG. 2D shows the change in Potential (μV) according to the rotation period (rotating rate, rpm) in magnetic field 4800 Oe.

In FIG. 2E, it can be verified that the electromotive force intensity changes accordingly by changing the intensity of the magnetic field to 3000 and 4800 Oe. For reference, FIG. 2E performed measurement at the rotation period (rotating rate) of 2700 rpm, and shows the change in Potential (μV) according to a loading amount at the magnetic fields 3000 and 4800 Oe.

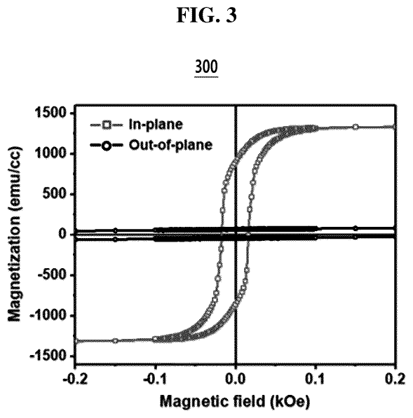

FIG. 3 is a graph showing the results of measuring the magnetic property of a stack using a vibrating sample magnetometer (VSM).

FIG. 3 shows results of measuring the magnetic property of a Co (10 nm)/Pt (10 nm) stack preferentially prepared to verify the chirality-induced spin selectivity property coupled with the electromotive force using the vibrating sample magnetometer (VSM).

Here, a case of applying the magnetic field in-plane was found to be an easy axis of magnetization. In particular, since residual magnetization (remanence) reaches 80% of a saturation magnetization value, spin in a specific direction may be stably injected into the chiral ferromagnetic nanocoil.

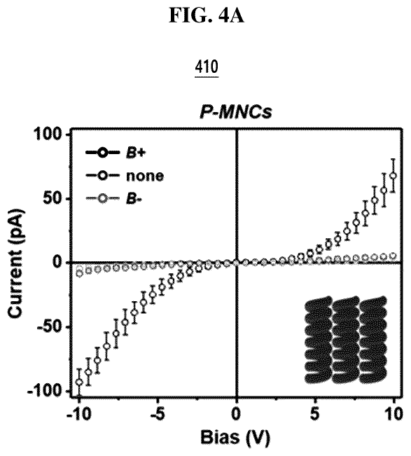

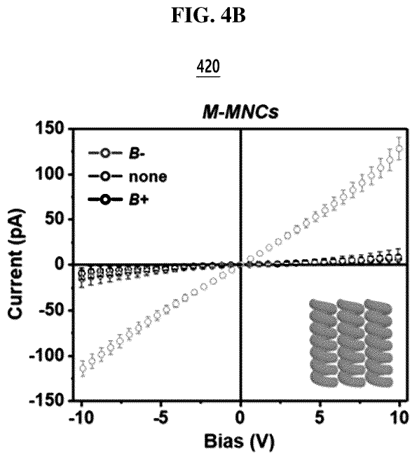

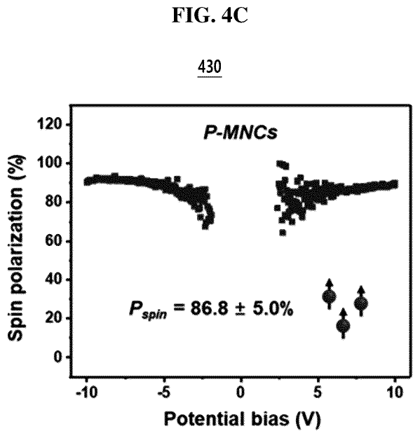

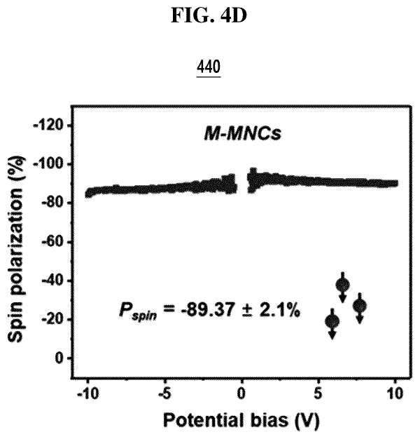

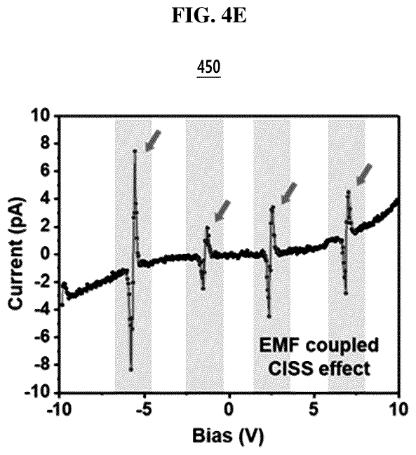

FIGS. 4A to 4E are graphs showing results of verifying the chirality-induced spin selectivity property of chiral ferromagnetic nanocoils that has right or left handedness.

FIGS. 4A and 4B are graphs showing results of verifying the chirality-induced spin selectivity property of chiral ferromagnetic nanocoils that has right headedness and left handedness, respectively.

FIGS. 4A and 4B clearly show different electrical conductivity according to the injected spin direction.

As a result, it is verified that this difference may result in very high spin polarization of about 86 to 89% as shown in results of FIGS. 4D and 4E. Also, in the case of momentarily applying the external magnetic field or rotating the electrode in the process in which this spin selective phenomenon occurs, it can be seen in FIG. 4E that the electromotive force may be generated simultaneously along with the chirality-induced spin selectivity property. This property is expected to maximize the chirality-induced spin selectivity property by accompanying a rectification in the future.

In FIG. 4E, current in the opposite direction may be implemented to be offset using a negative-positive-negative (NPN) semiconductor or a positive-negative-positive (PNP) transistor capable of performing rectification.

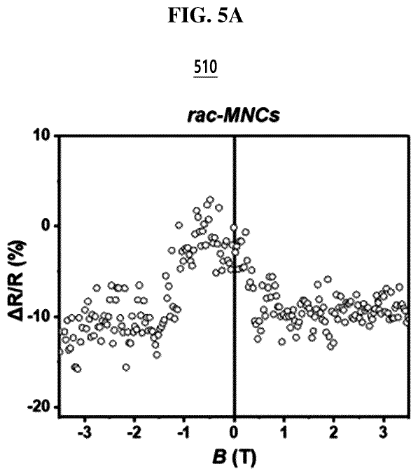

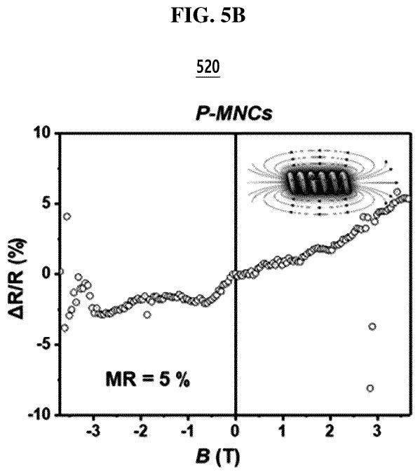

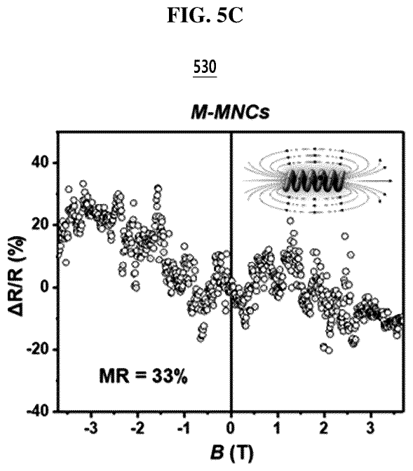

FIGS. 5A to 5C are graphs showing the magnetotransport property according to the direction (sign) of an external magnetic field.

Magnetotransport and magnetoresistance effect are very essential properties in a spintronic device. In particular, an inorganic material may be configured with a material with ferromagnetic properties compared to the existing organic material. Therefore, there is a potential for exhibiting a very efficient magnetotransport property in this measurement. In FIGS. 5A to 5C, the magnetotransport property of the material produced according to the direction of the external magnetic field can be verified.

Initially, in FIG. 5A, the magnetic property of a chiral ferromagnetic nanocoil without chirality was measured. In this case, although a negative magnetoresistance value is present, symmetrical results are acquired according to the direction of the external magnetic field.

On the other hand, in FIGS. 5B and 5C, the magnetotransport property of a chiral ferromagnetic nanocoil that twisted to the right and the magnetotransport property of a chiral ferromagnetic nanocoil that twisted to the left can be verified, respectively.

The above results show that, similar to the chirality-induced spin selectivity, the degree of scattering of spins varies depending on the direction in which the coil twisted and electrical characteristic changes.

The asymmetrical magnetotransport property refers to the property found in chiral materials and it is verified that similar results may be acquired through the present invention.

In the case of magnetic resistance verified here, a ferromagnetic material not found in organic molecules was used, so a very high asymmetric magnetic resistance value of up to 33% compared to the existing technologies showing the property of less than 0.1 to 1% was measured.

In addition to the existing high spin polarization, the following high magnetoresistance value is very unusual and may be widely applied in various physical, chemical, and life science fields in the future.

Ultimately, using the present invention, it is possible to provide a method of further maximizing the chiral-based magnetic property presented in the art while applying a very efficiently changing magnetic field to the inorganic material-based nanomaterial. In addition, it is possible to acquire an asymmetric electromotive force according to the chirality, and to acquire a relatively large magnetoresistance effect by taking advantage of a characteristic of a ferromagnetic material. Also, using the present invention, it is possible to utilize a prepared chiral ferromagnetic nanomaterial for a spintronic nanomaterial such as an actual magnetic memory, and to improve the degree of spin polarization by simultaneously expressing the chiral-based property, such as asymmetric electromotive force generation and chirality-induced spin selectivity (CISS) according to the direction by Faraday's law of electromagnetic induction occurring at nanoscale.

Although the example embodiments are described with reference to the accompanying drawings, it will be apparent to one of ordinary skill in the art that various alterations and modifications in form and details may be made in these example embodiments without departing from the spirit and scope of the claims and their equivalents. For example, suitable results may be achieved if the described techniques are performed in different order, and/or if components in a described system, architecture, device, or circuit are combined in a different manner, and/or replaced or supplemented by other components or their equivalents.

Therefore, other implementations, other example embodiments, and equivalents of the claims are to be construed as being included in the claims.

What is claimed is:

1. A device for measuring the asymmetrical magnetotransport property coupled with an electromotive force, the device comprising:
a rotating device that generates a rotational motion in an electrode;
a stack stacked on the electrode;
a chiral nanostructure in which a chiral ferromagnetic nanocoil is deposited on the stack,
wherein, in response to the rotating device rotating, chirality-induced spin selectivity or the asymmetrical magnetotransport property is measured through the chiral nanostructure.

2. The device of claim 1, wherein the stack has differences in characteristics by magnetic field between in-plane and out-of-plane and has the characteristic of having an easy axis of magnetization in the in-plane direction or the out-of-plane direction when an external magnetic field is absent.

3. The device of claim 2, wherein the stack includes a form in which a magnetic material, cobalt, iron, iron oxide, nickel, or alloy form and at least one of gold, platinum, tantalum, titanium, and heavy metal are stacked.

4. The device of claim 1, wherein the chiral ferromagnetic nanocoil is synthesized electrochemically using an anodic aluminum oxide nanopore template.

5. The device of claim 1, wherein the rotating device rotates the chiral nanostructure in a situation in which the magnetic field of constant intensity is applied and generates the electromotive force based on the flux that changes with respect to the rotating magnetic field.

6. The device of claim 5, wherein, based on the flux that changes with respect to the rotating magnetic field, the electromotive force is generated based on the surface of the nanostructures, electric field, unit length, unit time, magnetic density, unit area, electromotive force, number of windings of the nanocoil, and flux change, and is expressed as,
$$ϵ ( t ) \approx {nAB}_{0} ( 2 π f ) sin ( 2 π f t ) \qquad [ Equation 1 ]$$
where n denotes the concentration or total amount of chiral ferromagnetic nanocoil, A denotes an area inside the chiral ferromagnetic nanocoil, B₀ denotes the intensity of an external magnetic field, f denotes a rotation period, and t denotes an elapsed time.

7. The device of claim 5, wherein, in the chiral nanostructure, the chiral ferromagnetic nanocoils are aligned on the stack by applying a straight magnetic field.

8. The device of claim 1, further comprising:
a magnetic field application device capable of generating magnetic fields of various magnitudes,
wherein the rotating device generates the rotational motion in the electrode by the magnetic fields of various magnitudes generated by the magnetic field application device.

9. A manufacturing method of a device for measuring the asymmetrical magnetotransport property coupled with an electromotive force, the method comprising:
forming an electrode on a rotating device that generates a rotational motion;
preparing a stack by sequentially stacking one or more elements on the electrode, the stack having differences in characteristics by magnetic field between in-plane and out-of-plane and having the characteristic of having an easy axis of magnetization in the in-plane direction or the out-of-plane direction when an external magnetic field is absent;
forming a chiral nanostructure by depositing a chiral ferromagnetic nanocoil on the prepared stack,
wherein, in response to the rotating device rotating, chirality-induced spin selectivity or the asymmetrical magnetotransport property is measured through the chiral nanostructure.

10. The method of claim 9, wherein the forming of the chiral nanostructure by depositing the chiral ferromagnetic nanocoil on the prepared stack comprises:
synthesizing the chiral ferromagnetic nanocoil electrochemically using an anodic aluminum oxide nanopore template; and
depositing the chiral ferromagnetic nanocoil on the prepared stack by applying a straight magnetic field and by controlling the synthesized chiral ferromagnetic nanocoils to be aligned on the stack.
